(19) United States
(12) Patent Application Publication
(10) Pub. No.: US 2025/0332623 A1
(43) Pub. Date: Oct. 30, 2025

(54) ELECTRONIC DEVICE AND METHOD FOR FOREIGN OBJECT REMOVAL

(71) Applicant: Lenovo (Beijing) Limited, Beijing (CN)

(72) Inventors: Guowen ZHANG, Beijing (CN); Lei WU, Beijing (CN)

(21) Appl. No.: 19/194,073

(22) Filed: Apr. 30, 2025

(30) Foreign Application Priority Data
Apr. 30, 2024 (CN) 202410545094.4

(51) Int. Cl. B08B 9/053; B08B 13/00; H05K 5/02; H05K 7/20

(52) U.S. Cl. CPC B08B 9/053; B08B 13/00; H05K 5/0226; H05K 7/20145; H05K 7/20972; B08B 2209/053

(57) ABSTRACT

An electronic device includes a flexible display and a rotating shaft, the flexible display going around the rotating shaft to provide a visible part and an invisible part, the invisible part being on one side of the rotating shaft and the visible part being on the other side of the rotating shaft. The electronic device further includes a fan structure, located on one side of the rotating shaft for generating airflow; and an airflow guiding structure, configured to direct the airflow generated by the fan structure toward a gap. The gap is located between the flexible display and the rotating shaft.

### CROSS-REFERENCE TO RELATED APPLICATION

The present disclosure claims priority to Chinese Patent Application No. 202410545094.4, filed on Apr. 30, 2024, the entire content of which is incorporated herein by reference.

### TECHNICAL FIELD

The present disclosure relates to the field of flexible display and, in particular, to an electronic device and a foreign object removal method.

### BACKGROUND

A flexible display is bendable and is widely used in the screens of various electronic devices to achieve the effect of adjustable screen size. In order to meet the requirement of scalable screen size, the flexible screen on the electronic device can be set as a rollable screen, that is, the flexible display increases or decreases along the scroll. However, between the flexible display and the scroll there may be foreign objects, which may damage the flexible display.

### SUMMARY

One embodiment of the present disclosure provides an electronic device. The electronic device includes a flexible display, which includes a part that is visible and located on a first body of the electronic device and a part that is invisible and located on a second body of the electronic device. When a size of the part that is visible increases, a size of the part that is invisible decreases, and when the size of the part that is visible decreases, the size of the part that is invisible increases. The electronic device further includes a rotating shaft, the flexible display going around the rotating shaft to provide a visible part and an invisible part, the invisible part being on one side of the rotating shaft and the visible part being on the other side of the rotating shaft; a fan structure, located on one side of the rotating shaft for generating airflow; and an airflow guiding structure, configured to direct the airflow generated by the fan structure toward a gap. The gap is located between the flexible display and the rotating shaft.

Another embodiment of the present disclosure provides a foreign object removal method. The foreign object removal method includes generating a foreign object removal instruction if it is determined that the electronic device currently meets conditions for foreign object removal; and based on the foreign object removal instruction, controlling an airflow guiding structure of the electronic device to direct the airflow generated by a fan structure toward a gap between a flexible display and a rotating shaft of the electronic device. The flexible display includes a part that is visible and located on a first body of the electronic device and a part that is invisible and located on a second body of the electronic device. When a size of the part that is visible increases, a size of the part that is invisible decreases, and when the size of the part that is visible decreases, the size of the part that is invisible increases; the flexible display goes around the rotating shaft, forming a visible part and an invisible part. The invisible part is on one side of the rotating shaft and the visible part is on the other side of the rotating shaft, and a gap is formed between the flexible display and the rotating shaft.

### BRIEF DESCRIPTION OF THE DRAWINGS

In order to better illustrate the technical solutions in the embodiments of the present disclosure or related technologies, a brief introduction to the drawings required in the description of the embodiments or related technologies is provided below. It is evident that the drawings described below are merely some embodiments of this disclosure. For those skilled in the art, it is possible to obtain other drawings based on these illustrations without any inventive effort.

FIG. 1 is a schematic diagram of an electronic device according to an embodiment of the present disclosure.

FIG. 2 is a schematic diagram of airflow of a heat dissipation structure guided out through the first air outlet according to an embodiment of the present disclosure.

FIG. 3 is a schematic diagram of airflow of a heat dissipation structure guided out through second air outlet according to an embodiment of the present disclosure.

FIG. 4 is a schematic diagram of a flexible display going around a rotating shaft according to an embodiment of the present disclosure.

FIG. 5 is a schematic diagram of a cross-section of a hollow structure of a rotating shaft according to an embodiment of the present disclosure.

FIG. 6 is a schematic diagram of airflow generated by a fan structure entering/existing a rotating shaft by passing through a hole in rotating shaft according to an embodiment of the present disclosure.

FIG. 7 is a schematic diagram of interior of a rotating shaft according to an embodiment of the present disclosure.

FIG. 8 is a flowchart of a foreign object removal method according to an embodiment of the present disclosure.

### DETAILED DESCRIPTION OF THE EMBODIMENTS

The technical solutions in the embodiments of the present disclosure will be clearly and completely described below in conjunction with the drawings in the embodiments of the present disclosure. Obviously, the described embodiments are only part of the embodiments of the disclosure application, rather than all the embodiments. Based on the embodiments of this disclosure, all other embodiments that a person skilled in the art can derive without making any inventive effort are within the scope of protection of this disclosure.

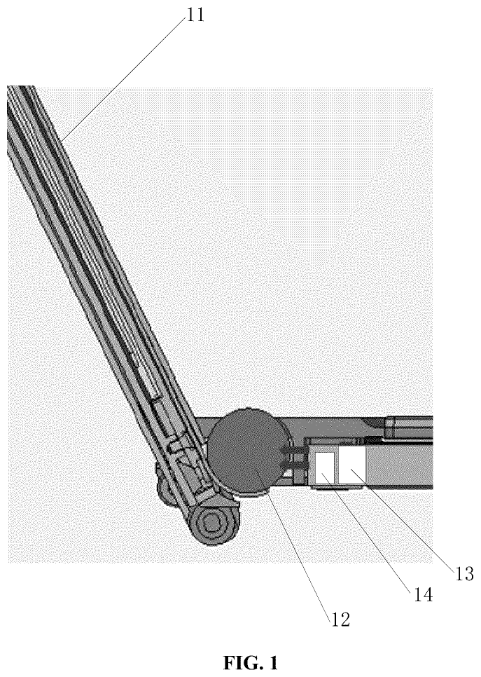

The present disclosure discloses an electronic device, and a schematic diagram of the structure of an exemplary electronic device is shown in FIG. 1, including: a flexible display 11, a rotating shaft 12, a fan structure 13, and an airflow guiding structure 14.

In one embodiment, the flexible display can include a part that is visible and located on the first body of the electronic device and a part that is invisible and located on the second body of the electronic device. When the size of the visible part increases, the size of the invisible part decreases, and when the size of the visible part decreases, the size of the invisible part increases.

In one embodiment, the flexible display 11 goes around the rotating shaft 12 and provides a visible part and an invisible part. For example, the flexible display 11 may roll around, wrap around, curved around, or extend around the rotating shaft 12. In some embodiments, the flexible display 11 may or may not fold at the rotating shaft 12. The invisible part is on one side of the rotating shaft 12 and the visible part is on the other side of the rotating shaft 12.

The fan structure 13 is located on one side of the rotating shaft 12 and is capable of generating airflow.

The airflow guiding structure 14 is configured to direct the airflow generated by the fan structure toward a gap. The gap is the space formed between the flexible display 11 and the rotating shaft 12.

The electronic device includes a first body and a second body. The screen of the electronic device is a flexible display, with one part of the flexible display located on the first body of the electronic device and the other part located on the second body of the electronic device. The part of the flexible display on the first body of the electronic device is the visible part and the part of the flexible display on the second body is the invisible part. The visible part of the flexible display is capable of displaying the output screen of the electronic device, and the invisible part of the flexible display does not display any screen content.

The size of the visible part and the invisible part of the flexible display can change. When the size of the visible part of the flexible display decreases, the reduced portion is adjusted to the invisible part, causing the size of the invisible part to increase. The increased portion of the invisible part corresponds to the reduced portion of the visible part, meaning that the size of the visible part of the flexible display used for displaying the output screen of the electronic device decreases. When the size of the visible part of the flexible display increases, the size of the invisible part decreases. The decreased portion of the invisible part is adjusted to the increased portion of the visible part, meaning that the size of the visible part of the flexible display used for displaying the output screen of the electronic device increases.

The flexible display goes around the rotating shaft, forming a visible part and an invisible part. The invisible part is located on one side of the rotating shaft and the visible part is located on the other side of the rotating shaft. When the size of the visible part of the flexible display increases or decreases, the flexible display moves along the rotating shaft, thereby increasing or decreasing the size of the visible part.

When the flexible display goes around the rotating shaft, a narrow gap is formed between the flexible display and the rotating shaft. If there are foreign objects in this gap, such as dust, hair and paper scraps, these foreign objects may damage the flexible display, e.g. scratching the flexible display, when it moves along the rotating shaft.

In order to ensure that the flexible display is not damaged by foreign objects in the gap, in this solution, the airflow formed by the fan structure is directed toward the gap through the airflow guiding structure, so that the foreign objects in the gap are blown away by the airflow, thereby preventing the foreign objects from damaging the flexible display and prolonging the lifespan of the flexible display.

The rotating shaft can be arranged at the second body of the electronic device, or it can be placed at the connection point between the first body and the second body.

The part of the flexible display on one side of the rotating shaft is the invisible part and the part of the flexible display on the other side of the rotating shaft is the visible part. If the invisible part is located on the first side of the rotating shaft and the visible part is located on the second side of the rotating shaft, the first side of the rotating shaft is the second body and the second side of the rotating shaft is the first body.

The fan structure and the airflow guiding structure are positioned on the same side of the rotating shaft, such as both the fan structure and the airflow guiding structure are located on the first side of the rotating shaft, that is, arranged on the second body of the electronic device. At this time, the airflow guiding structure and fan structure do not affect the output content displayed on the visible part. The airflow guiding structure directs the airflow generated by the fan structure to the gap between the rotating shaft and the flexible display, allowing the airflow to blow away foreign objects in the gap, thereby preventing damage to the flexible screen by foreign objects in the gap when the flexible screen moves along the rotating shaft.

The electronic device the present disclosure discloses includes a flexible display, a rotating shaft, a fan structure and an airflow guiding structure. The flexible display includes a visible part located on the first body of the electronic device and an invisible part located on the second body of the electronic device. When the size of the visible part increases, the size of the invisible part decreases, and when the size of the visible part decreases, the size of the invisible part increases. The flexible display goes around the rotating shaft, forming a visible part and an invisible part. The invisible part is on one side of the rotating shaft and the visible part is on the other side of the rotating shaft. The fan structure is located on one side of the rotating shaft and is capable of generating airflow. The airflow guiding structure is configured to direct the airflow generated by the fan structure toward a gap. The gap is the space formed between the flexible display and the rotating shaft. In the present disclosure, the airflow formed by the fan structure is directed toward the gap between the flexible display and the rotating shaft through the airflow guiding structure, so that the foreign objects in the gap are blown away by the airflow, thereby preventing the foreign objects from damaging the flexible display and prolonging the lifespan of the flexible display.

The present disclosure discloses an electronic device, and a schematic diagram of the structure of the electronic device is shown in FIG. 1, including: a flexible display 11, a rotating shaft 12, a fan structure 13 and an airflow guiding structure 14.

In addition to the same structure as the previous embodiment, the fan structure in this embodiment includes: a heat dissipation fan, a first air outlet and a second air outlet.

The heat dissipation fan is configured to create airflow.

The first air outlet faces the exterior of the electronic device, and the airflow guiding structure is capable of directing the airflow generated by the heat dissipation fan toward the outside of the electronic device through the first air outlet.

The second air outlet faces the direction of the rotating shaft, and the airflow guiding structure is capable of directing the airflow generated by the heat dissipation fan toward the gap between the flexible display and the rotating shaft through the second air outlet.

During the operation of an electronic device, its internal processing structure performs data processing, which causes the temperature of the internal components to rise. Therefore, to dissipate heat from the electronic device, a heat dissipation structure is usually provided in the electronic device.

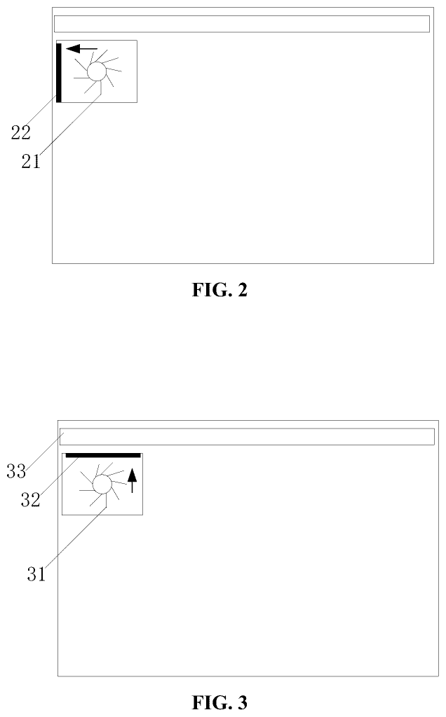

The heat dissipation structure primarily includes a heat dissipation fan, which is configured to generate airflow. To achieve the function of dissipating heat for the electronic device, the heat dissipation structure also includes a first air outlet, which faces the exterior of the electronic device. When the airflow is directed through the first air outlet, the purpose of reducing the temperature of the internal components of the electronic device through the airflow is achieved. The schematic diagram of the airflow of the heat dissipation structure being guided out through the first air outlet is shown in FIG. 2, including a heat dissipation fan 21 and a first air outlet 22. The direction indicated by the arrow in FIG. 2 is the direction in which the airflow id discharged thorough the first air outlet.

In the present disclosure, in order to achieve the function of removing foreign object between the flexible display and the rotating shaft through the fan structure, it is necessary to add a second air outlet to the fan structure.

The second air outlet faces the direction of the rotating shaft. When the airflow of the heat dissipation structure is discharged through the second air outlet, the airflow blows away the foreign objects in the gap between the flexible display and the rotating shaft, thereby effectively preventing damage to the flexible display by foreign objects in the gap and increasing the lifespan of the flexible display.

The schematic diagram of the airflow of a heat dissipation structure being guided out through the second air outlet is shown in FIG. 3, including: a heat dissipation fan 31, a second air outlet 32 and a rotating shaft 33. The direction indicated by the arrow in FIG. 3 is the direction in which the airflow is guided out through the second air outlet.

It should be noted that the fan structure can be positioned at one end of the side of the rotating shaft in the electronic device, as shown in FIGS. 2 and 3. The fan structure can also be positioned at multiple intervals along the side of the rotating shaft in the electronic device where a fan structure can be placed at regular distances from one end of the rotating shaft side until reaching the other end of the rotating shaft. Additionally, the fan structure can be positioned at the middle position of the side of the rotating shaft in the electronic device, or at the other end of the side of the rotating shaft in the electronic device.

The electronic device includes an airflow guiding structure, which can control the direction of the airflow from the fan structure, that is, the airflow guiding structure can control the outlet direction of the airflow formed by the heat dissipation fan. When the electronic device needs to dissipate heat, the airflow guiding structure controls the airflow of the fan to be discharged through the first air outlet along the direction indicated by the arrow in FIG. 2, so that the heat in the electronic device can be discharged to the outside of the electronic device through the airflow. When the electronic device needs to clean foreign objects in the gap, the airflow guiding structure controls the airflow of the fan to be discharged through the second air outlet along the direction indicated by the arrow in FIG. 3 to blow the airflow to the gap between the flexible display and the rotating shaft to blow foreign objects in the gap to the outside of the gap to prevent damage to the flexible display caused by foreign objects in the gap.

The electronic device the present disclosure discloses includes a flexible display, a rotating shaft, a fan structure and an airflow guiding structure. The fan structure includes a heat dissipation fan, a first air outlet and a second air outlet. The heat dissipation fan is configured to generate airflow. The first air outlet faces the exterior of the electronic device, and the airflow guiding structure is capable of directing the airflow formed by the heat dissipation fan through the first air outlet toward the exterior of the electronic device. The second air outlet faces the direction of the rotating shaft, and the airflow guiding structure is capable of directing the airflow from the heat dissipation fan through the second air outlet toward the gap between the flexible display and the rotating shaft. This present disclosure sets two air outlets in different directions for the fan structure, so that different functions of the heat dissipation fan can be realized through different air outlets, that is, the heat dissipation fan can dissipate heat for the electronic device through the first air outlet, and can clean foreign objects in the gap between the flexible display and the rotating shaft through the second air outlet. The present disclosure only needs to perform simple modification to the existing structure to enable the heat dissipation fan to serve different functions, which not only ensures the heat dissipation of the electronic device, but only extends the lifespan of the flexible display.

Furthermore, the electronic device the present disclosure discloses can also include:

A controller, which is configured to generate a foreign object removal instruction when it detects a change in the status of the flexible display, and based on the foreign object removal instruction, controls the airflow guiding structure to blow the airflow through the second air outlet to the gap between the flexible display and the rotating shaft.

The change in the status of the flexible display includes at least one of the following: the visible part of the flexible display switches from a display state to a non-display state, the visible part of the flexible display switches from a non-display state to a display state, or the size of the visible part of the flexible display increases or decreases.

Specifically, the electronic device can monitor the status of the flexible display. For example, the electronic device can determine whether the visible part of the flexible display is currently switched from the display state to the non-display state. If the visible part of the flexible display switches from the display state to the non-display state, it indicates that the electronic device is currently switched from the power-on state to the power-off state or the standby state. At this time, the gap between the flexible display and the rotating shaft needs to be cleaned to ensure that there is no foreign object in the gap to prevent damage to the flexible display. If it is determined that the visible part of the flexible display is always in the display state, that is, it has not switched its state, then at this time, the gap between the flexible display and the rotating shaft does not need to be cleaned to save energy.

In another example, the electronic device can determine whether the visible part of the flexile display is currently switched from the non-display state to the display state. If the visible part of the flexible display switches from a non-display state to a display state, it indicates that the electronic device is currently switched from the power-off state or the standby state to the powered-on state. At this time, the gap between the flexible display and the rotating shaft needs to be cleaned to ensure that there are no foreign objects in the gap to prevent damage to the flexible display. If it is determined that the visible part of the flexible display is currently always in a non-display state, that is, it has not switched states, then at this time, there is no need to clean the gap between the flexible display and the rotating shaft to save energy.

In yet another example, the electronic device can determine whether the size of the visible part of the flexible display increases or decreases. If the electronic device determines that the size of the visible part of the flexible display increases or decreases, meaning that the flexible display moves relative to the rotating shaft, then it is necessary to clean the gap between the flexible display and the rotating shaft to prevent foreign object in the gap between the flexible display and the rotating shaft from damaging the flexible display during the movement of the flexible display relative to the rotating shaft. If the electronic device determines that the size of the visible part of the flexible screen is not changed, the gap does not need to be cleaned to save energy.

When a change in the state of the flexible display is detected, the controller can generate a foreign object removal instruction based on the change in the state of the flexible display, and control the fan structure and/or the airflow guiding structure based on the foreign object removal instruction, so that the airflow guiding structure can blow the airflow formed by the fan structure through the second air outlet to the gap between the flexible display and the rotating shaft, thereby achieving the purpose of clearing foreign objects in the gap and ensuring that the flexible display is not damaged.

The controller in the electronic device, based on the foreign object removal instruction, can control the state of the fan structure and/or the airflow guiding structure. Specifically, the controller can control whether the fan structure is in an operating state or a stopped state. If the fan structure is in an operating state, the controller can also control whether the first air outlet or the second air outlet of the fan structure is open, thereby directing the airflow formed by the fan structure either toward the outside of the electronic device or toward the gap between the flexible display and the rotating shaft. If the fan structure is controlled based on the foreign object removal instruction, the controller can open the second air outlet in the fan structure. Alternatively, the controller can control the closing of the first air outlet or the second air outlet of the fan structure. If the controller controls the fan structure based on the foreign object removal instruction, it can close the first air outlet based on the instruction, in which case the second air outlet will necessarily be in the open state.

In addition, the controller can also control the rotation direction of the heat dissipation fan in the fan structure based on the foreign matter removal instruction, and the airflow formed by the fan structure can be guided to the second air outlet through the airflow guiding structure by adjusting the rotation direction of the fan structure. For example, when the rotation direction of the fan structure is in a first direction, the airflow formed by the heat dissipation fan can be guided to the first air outlet through the airflow guiding structure, and when the rotation direction of the fan structure is in a second direction, the airflow formed by the heat dissipation fan can be guided to the second air outlet through the airflow guiding structure.

In addition, the controller can also control the rotation speed of the heat dissipation fan in the fan structure based on the foreign matter removal instruction to form airflows of different strengths through different rotation speeds to clean foreign object of different sizes in the gap between the flexible display and the rotating shaft based on airflows of different strengths. Based on the size of the foreign object in the gap, the electronic device can determine the rotation speed of the heat dissipation fan to completely clean the foreign object in the gap, thereby protecting the flexible display.

Furthermore, when the controller controls the fan structure based on the foreign matter removal instruction, the rotation speed of the heat dissipation fan in the fan structure can be further controlled based on whether the electronic device has a heat dissipation requirement.

When it is determined that the state of the flexible display has changed, a foreign object removal instruction is generated, and based on the foreign object removal instruction, the airflow guiding structure is controlled to blow the airflow through the second air outlet to the gap between the flexible display and the rotating shaft, and the speed of the heat dissipation fan in the fan structure can be adjusted.

At this time, if it is determined that the electronic device has no heat dissipation requirement, the rotation speed of the heat dissipation fan can be controlled to a first speed. If the electronic device has a heat dissipation requirement, the rotation speed of the heat dissipation fan can be controlled to a second speed. The second speed is greater than the first speed to ensure that the airflow formed by the heat dissipation fan can not only meet the heat dissipation requirement, but also supply the airflow required to remove foreign objects in the gap between the flexible display and the rotating shaft.

The controller controls the state of the airflow guiding structure, which can specifically be: the controller can control the airflow guiding structure to be in different states in order to control the direction of the airflow.

When the controller sets the airflow guiding structure to the first state, the airflow direction of the airflow guiding structure aligns with the first air outlet of the fan structure, that is, at this time, the airflow guiding structure directs the airflow generated by the heat dissipation fan in the fan structure toward the first air outlet. When the controller sets the airflow guiding structure to the second state, the airflow direction of the airflow guiding structure aligns with the second air outlet of the fan structure, that is, at this time, the airflow guiding structure directs the airflow generated by the heat dissipation fan toward the second air outlet.

The present disclosure discloses an electronic device, and a schematic diagram of the structure of the electronic device is shown in FIG. 1, including: a flexible display 11, a rotating shaft 12, a fan structure 13 and an airflow guiding structure 14.

In addition to the same structure as the previous embodiment, the rotating shaft in this embodiment is a hollow structure, and multiple openings are arranged on the wall of the rotating shaft.

The fan structure is located at the first end of the rotating shaft. The airflow generated by the fan structure enters the interior of the rotating shaft through the opening at the first end of the rotating shaft, and blows from the interior of the rotating shaft to the gap between the flexible display and the non-first end of the rotating shaft through the opening at the non-first end of the rotating shaft.

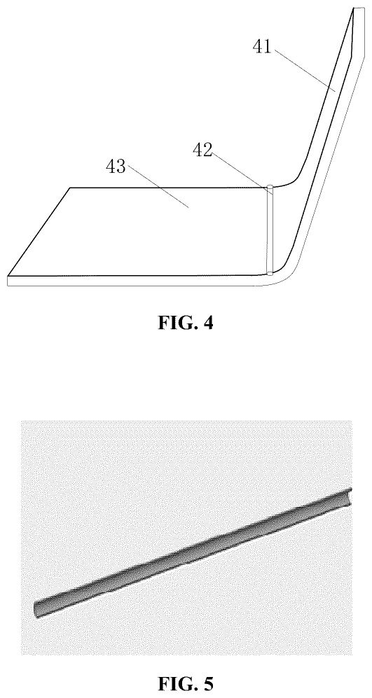

The flexible display goes around the rotating shaft, forming a visible part and an invisible part, as shown in FIG. 4, including the visible part of the flexible display 41, invisible part of the flexible display 42 and the rotating shaft 43.

The fan structure is arranged at the first end of the first side of the rotating shaft, as shown in FIG. 3. At this time, in order to ensure that the airflow generated by the fan structure can blow all the gaps between the flexible display and the rotating shaft, it is necessary to set the rotating shaft as a hollow structure. A cross-sectional view of the hollow structure of the rotating shaft is shown in FIG. 5.

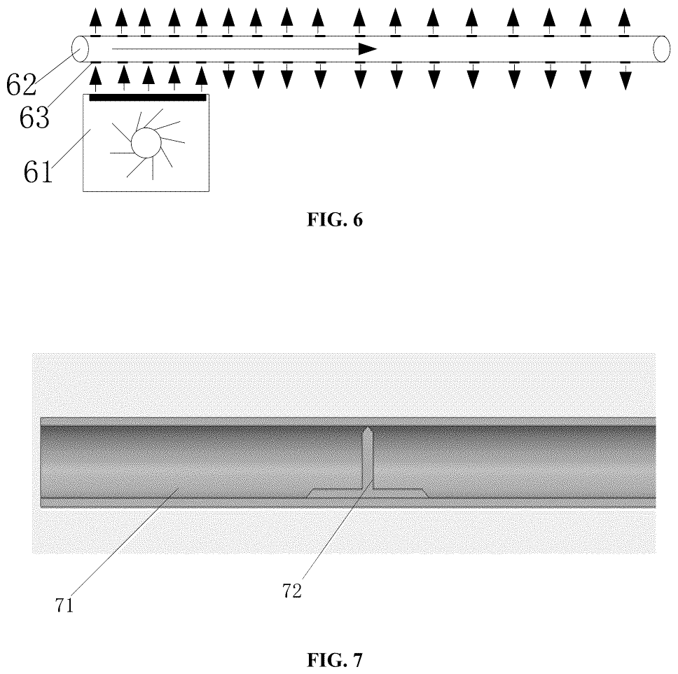

Multiple openings are set on the wall of the rotating shaft that has a hollow structure. The airflow generated by the fan structure enters the interior of the rotating shaft through the openings at the first end on the first side. Then, the airflow exits the rotating shaft through openings at other positions to enter the gap between the flexible display and the rotating shaft, as shown in FIG. 6, which includes: a fan structure 61, a rotating shaft 62, and multiple openings 63 on the wall of the rotating shaft.

The fan structure 61 generates airflow, which enters the hollow structure of the rotating shaft through the opening on the wall of the rotating shaft at a position corresponding to the fan structure 61. The airflow flows inside the hollow structure of the rotating shaft. As the airflow flows inside the hollow structure of the rotating shaft, if the airflow encounters the opening 63, a portion of the airflow will pass through the opening to reach the outside of the hollow structure of the rotating shaft. For the airflow that reaches the outside of the hollow structure of the rotating shaft, a portion of it will reach the gap between the flexible display and the rotating shaft. This portion of the airflow can clear foreign objects in the gap at the opening.

Except for the opening located at the first end of the first side of the rotating shaft, airflow can flow from the inside of the hollow structure to the outside through each of the other openings on the rotating shaft, thereby clearing foreign objects at different positions of the gap between the flexible display and the rotating shaft by utilizing multiple openings at different positions on the rotating shaft.

The faster the speed of the heat dissipation fan in the fan structure, the greater the intensity of the airflow, and the greater the intensity of the airflow allocated to each opening on the rotating shaft, the more effectively it can remove foreign objects that are difficult to remove from the gaps, thereby improving the cleaning effect of foreign objects in the gaps and preventing the flexible display from being damaged by foreign objects in the gaps.

The electronic device the present disclosure discloses includes: a flexible display, a rotating shaft, a fan structure and an airflow guiding structure. The rotating shaft is a hollow structure with multiple openings on the wall of the rotating shaft. The fan structure is located at the first end of the rotating shaft. The airflow generated by the fan structure enters the interior of the rotating shaft through the opening at the first end of the rotating shaft, and blows from the interior of the rotating shaft to the gap between the flexible display and the non-first end of the rotating shaft through the opening at the non-first end of the rotating shaft.

The present disclosure arranges multiple openings on the wall of a hollow rotating shaft so that the airflow generated by the fan structure can enter the rotating shaft through the openings on the wall and reach the gap between the flexible display and the rotating shaft through the openings at other positions. This avoids the situation where the fan structure is only located at the first end of the rotating shaft and can only clean foreign objects in the gap at the first end. Instead, the openings at different positions on the rotating shaft can be configured to clean foreign objects in the gap at different positions, thereby ensuring the cleaning effect of foreign objects in the gap and improving the service life of the flexible display.

In addition, a slider may be provided inside the rotating shaft of a hollow structure in the electronic device that the present disclosure discloses. The slider can slide within the rotating shaft to remove foreign objects inside the rotating shaft.

Foreign objects inside the rotating shaft can be removed either by airflow or by a slider.

If cleaning by a slider, a slider needs to be installed inside the rotating shaft, as shown in FIG. 7, which includes a rotating shaft 71 and a slider 72.

The slider slides back and forth inside the rotating shaft, thereby pushing foreign objects inside the rotating shaft to one end of the rotating shaft, thereby avoiding foreign objects from being retained inside the rotating shaft and preventing foreign objects inside the rotating shaft from entering the gap between the flexible display and the rotating shaft along the airflow when foreign objects are removed by airflow.

Storage spaces can be provided at both ends of the rotating shaft. When the slider moves to one end inside the rotating shaft, any foreign objects present can be pushed into the storage space at that end, thereby preventing the foreign object from remaining inside the shaft.

In addition, the slider can also move within the rotating shaft based on the airflow generated by the fan structure that enters the interior of the rotating shaft.

The movement of the slider within the rotating shaft can be directly achieved by airflow, without the need for any additional electrical signals' support. As long as the airflow generated by the fan structure enters the rotating shaft, the airflow can push the slider toward the second end of the rotating shaft. During this process, if there are any foreign objects along the path of the slider's movement, they will be pushed toward the second end of the rotating shaft, allowing them to enter the storage space at the second end, thereby preventing them from remaining inside the rotating shaft, thereby avoiding them entering the gap between the flexible display and the rotating shaft to cause damage to the flexible display.

When the fan structure no longer generates airflow, or when the airflow generated by the fan structure no longer enters the interior of the rotating shaft, the slider can return from the second end of the rotating shaft to its original position. The original position may be: the first end of the rotating shaft, or a location within the rotating shaft near the first end.

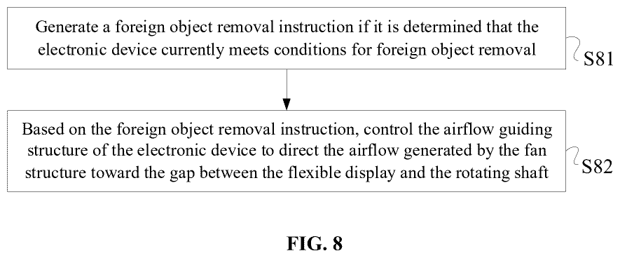

The present disclosure discloses a foreign object removal method, the flowchart of which is shown in FIG. 8, including: S81, generating a foreign object removal instruction if it is determined that the electronic device currently meets the conditions for foreign object removal; and S82, based on the foreign object removal instruction, controlling the airflow guiding structure of the electronic device to direct the airflow generated by the fan structure toward the gap between the flexible display and the rotating shaft of the electronic device.

The flexible display includes a visible part located on the first body of the electronic device and an invisible part located on the second body of the electronic device. When the size of the visible part increases, the size of the invisible part decreases, and when the size of the visible part decreases, the size of the invisible part increases. The flexible display goes around the rotating shaft, forming a visible part and an invisible part. The invisible part is on one side of the rotating shaft and the visible part is on the other side of the rotating shaft. A gap is formed between the flexible display and the rotating shaft.

Moreover, based on the foreign object removal instruction, controlling the airflow guiding structure of the electronic device to direct the airflow generated by the fan structure toward the gap between the flexible display and the rotating shaft of the electronic device, including:
adjusting the rotation direction of the heat dissipation fan based on a foreign object removal instruction, so that the airflow guiding structure directs airflow toward the gap between the flexible display and the rotating shaft of the electronic device.

Moreover, based on the foreign object removal instruction, controlling the airflow guiding structure of the electronic device to direct the airflow generated by the fan structure toward the gap between the flexible display and the rotating shaft of the electronic device, including:
based on the foreign object removal instruction, controlling the opening of the second air outlet in the fan structure, which is aligned with the direction of the gap between the flexible display and the rotating shaft, so that the airflow guiding structure blows the airflow generated by the fan structure to the gap between the flexible display and the rotating shaft of the electronic device through the second air outlet.

Moreover, determining whether the electronic device currently meets the foreign object removal conditions, including: determining whether the state of the flexible display changes. The change in the status of the flexible display includes at least one of the following: the visible part of the flexible display switches from a display state to a non-display state, the visible part of the flexible display switches from a non-display state to a display state, or the size of the visible part of the flexible display increases or decreases.

The foreign object removal method the present disclosure discloses is implemented based on the electronic device disclosed above and will not be repeated here.

The foreign object removal method the present disclosure discloses applies to electronic device. Electronic device includes: a flexible display, a rotating shaft, a fan structure and an airflow guiding structure. If it is determined that the electronic device currently meets the conditions for foreign object removal, generating a foreign object removal instruction; and based on the foreign object removal instruction, controlling the airflow guiding structure of the electronic device to direct the airflow generated by the fan structure toward the gap between the flexible display and the rotating shaft of the electronic device. The flexible display includes a visible part located on the first body of the electronic device and an invisible part located on the second body of the electronic device. When the size of the visible part increases, the size of the invisible part decreases, and when the size of the visible part decreases, the size of the invisible part increases. The flexible display goes around the rotating shaft, forming a visible part and an invisible part. The invisible part is on one side of the rotating shaft and the visible part is on the other side of the rotating shaft. The fan structure is located on one side of the rotating shaft and is capable of generating airflow. The airflow guiding structure is configured to direct the airflow generated by the fan structure toward a gap. The gap is the space formed between the flexible display and the rotating shaft. In this solution, the airflow formed by the fan structure is directed toward the gap between the flexible display and the rotating shaft through the airflow guiding structure, so that the foreign objects in the gap are blown away by the airflow, thereby preventing the foreign objects from damaging the flexible display and prolonging the lifespan of the flexible display.

The various embodiments in the present disclosure are described in a progressive manner. Each embodiment focuses on the differences compared to other embodiments, and the similar or identical parts among the embodiments can be referenced to one another. As for the device disclosed in the present disclosure, since it corresponds to the method disclosed in the embodiments, its description is relatively brief, and the relevant details can be referred to in the method section.

Those skilled in the art will also understand that the units and algorithm steps described in the examples of the disclosed embodiments can be implemented in electronic hardware, computer software, or a combination of both. To clearly illustrate the interchangeability between hardware and software, the components and steps of the examples have been described above in terms of their functions in a general manner. Whether these functions are performed in hardware or software depends on the specific application and design constraints of the technical solution. A person skilled in the art may implement the described functions in different ways for each particular application. However, such implementations should not be considered as going beyond the scope of the present disclosure.

The steps of the methods or algorithms described in the disclosed embodiments can be implemented directly in hardware, in software modules executed by a processor, or in a combination of both. The software modules may be stored in random access memory (RAM), memory, read-only memory (ROM), electrically programmable ROM, electrically erasable programmable ROM, registers, hard disks, removable disks, CD-ROMs, or any other form of storage medium known in the art.

The above description of the disclosed embodiments enables those skilled in the art to implement or use the present application. Various modifications to these embodiments will be apparent to those skilled in the art, and the general principles defined herein may be implemented in other embodiments without departing from the spirit or scope of the present application. Therefore, the present disclosure should not be limited to the embodiments shown herein, but rather should be accorded the broadest scope consistent with the principles and novel features disclosed.

What is claimed is:

1. An electronic device, comprising:
a flexible display, comprising a part that is visible and located on a first body of the electronic device and a part that is invisible and located on a second body of the electronic device, wherein
when a size of the part that is visible increases, a size of the part that is invisible decreases, and when the size of the part that is visible decreases, the size of the part that is invisible increases;
a rotating shaft, the flexible display going around the rotating shaft to provide a visible part and an invisible part, wherein
the invisible part is on one side of the rotating shaft and the visible part is on the other side of the rotating shaft;
a fan structure, located on one side of the rotating shaft for generating airflow; and
an airflow guiding structure, configured to direct the airflow generated by the fan structure toward a gap, wherein
the gap is located between the flexible display and the rotating shaft.

2. The electronic device according to claim 1, wherein the fan structure comprises:
a heat dissipation fan, configured to generate the airflow;
a first air outlet, facing toward outside of the electronic device, wherein
the airflow guiding structure is capable of directing the airflow generated by the heat dissipation fan toward the outside of the electronic device through the first air outlet; and
a second air outlet, facing toward the rotating shaft, wherein
the airflow guiding structure is capable of directing the airflow generated by the heat dissipation fan toward the gap between the flexible display and the rotating shaft through the second air outlet.

3. The electronic device according to claim 2, further including:
a controller, configured to generate a foreign object removal instruction in response to a change in status of the flexible display being determined and, based on the foreign object removal instruction, control the airflow guiding structure to blow the airflow through the second air outlet to the gap between the flexible display and the rotating shaft.

4. The electronic device according to claim 3, wherein the change in the status of the flexible display includes at least one of following:
the visible part of the flexible display switches from a display state to a non-display state,
the visible part of the flexible display switches from a non-display state to a display state, or
a size of the visible part of the flexible display increases or decreases.

5. The electronic device according to claim 3, wherein, based on the foreign object removal instruction, the controller is further configured to:
adjust a rotation direction of the heat dissipation fan to form an airflow directed toward the second air outlet through the airflow guiding structure; or
control the first air outlet to shut off and control the second air outlet to open up.

6. The electronic device according to claim 1, wherein:
the rotating shaft includes a hollow structure and a plurality of openings are arranged on a wall of the rotating shaft; and
the fan structure is located at a first end of the rotating shaft.

7. The electronic device according to claim 1, wherein:
the airflow generated by the fan structure is controlled to enter inside of the rotating shaft through a first opening of the plurality of openings at the first end of the rotating shaft, and blow from the inside of the rotating shaft to the gap between the flexible display and a non-first end of the rotating shaft through a second opening of the plurality of openings at the non-first end of the rotating shaft.

8. The electronic device according to claim 1, wherein:
a slider is provided in the rotating shaft; and
the slider is capable of sliding within the rotating shaft to remove foreign objects from the inside of the rotating shaft.

9. The electronic device according to claim 8, wherein:
the slider is configured to move within the rotating shaft based on the airflow generated by the fan structure and entered into the rotating shaft.

10. A foreign object removal method, comprising:
generating a foreign object removal instruction if it is determined that the electronic device currently meets conditions for foreign object removal; and
based on the foreign object removal instruction, controlling an airflow guiding structure of the electronic device to direct the airflow generated by a fan structure toward a gap between a flexible display and a rotating shaft of the electronic device, wherein
the flexible display comprises a part that is visible and located on a first body of the electronic device and a part that is invisible and located on a second body of the electronic device, wherein
when a size of the part that is visible increases, a size of the part that is invisible decreases, and when the size of the part that is visible decreases, the size of the part that is invisible increases,
the flexible display goes around the rotating shaft, forming a visible part and an invisible part, the invisible part is on one side of the rotating shaft and the visible part is on the other side of the rotating shaft, and
a gap is formed between the flexible display and the rotating shaft.

11. The method according to claim 10, wherein the fan structure comprises:
a heat dissipation fan, configured to generate the airflow.

12. The method according to claim 11, wherein the fan structure further comprises:
a first air outlet, facing toward outside of the electronic device, wherein the airflow guiding structure is capable of directing the airflow generated by the heat dissipation fan toward the outside of the electronic device through the first air outlet; and
a second air outlet, facing toward the rotating shaft, wherein the airflow guiding structure is capable of directing the airflow generated by the heat dissipation fan toward the gap between the flexible display and the rotating shaft through the second air outlet.

13. The method according to claim 11, wherein controlling the airflow guiding structure to direct the airflow toward the gap between the flexible display and the rotating shaft includes:
adjusting a rotation direction of the heat dissipation fan based on the foreign object removal instruction, so that the airflow guiding structure directs airflow toward the gap between the flexible display and the rotating shaft of the electronic device.

14. The method according to claim 12, wherein controlling the airflow guiding structure to direct the airflow toward the gap between the flexible display and the rotating shaft includes:
controlling the first air outlet to shut off and controlling the second air outlet to open, based on the foreign object removal instruction.

15. The method according to claim 10, wherein:
the rotating shaft includes a hollow structure and a plurality of openings are arranged on a wall of the rotating shaft; and
the fan structure is located at a first end of the rotating shaft.

16. The method according to claim 15, wherein controlling the airflow guiding structure to direct the airflow toward the gap between the flexible display and the rotating shaft includes:
controlling the airflow generated by the fan structure to enter inside of the rotating shaft through a first opening of the plurality of openings at the first end of the rotating shaft, and to blow from the inside of the rotating shaft to the gap between the flexible display and a non-first end of the rotating shaft through a second opening of the plurality of openings at the non-first end of the rotating shaft.

17. The method according to claim 16, wherein controlling the airflow guiding structure to direct the airflow toward the gap between the flexible display and the rotating shaft includes:
based on the foreign object removal instruction, controlling an air outlet in the fan structure to open, the air outlet being aligned with the gap between the flexible display and the rotating shaft,
wherein the airflow guiding structure blows the airflow generated by the fan structure to the gap between the flexible display and the rotating shaft of the electronic device through the opened air outlet.

18. The method according to claim 10, wherein the conditions for foreign object removal include a change in status of the flexible display, the change including at least one of following:
the visible part of the flexible display switches from a display state to a non-display state,
the visible part of the flexible display switches from a non-display state to a display state, or
a size of the visible part of the flexible display increases or decreases.

19. The method according to claim 10, wherein:
a slider is provided in the rotating shaft; and
the slider is capable of sliding within the rotating shaft to remove foreign objects from the inside of the rotating shaft.

20. The method according to claim 17, wherein:
the slider is configured to move within the rotating shaft based on the airflow generated by the fan structure and entered into the rotating shaft.
